(19) United States
(12) Patent Application Publication
(10) Pub. No.: US 2025/0174442 A1
(43) Pub. Date: May 29, 2025

(54) SUBSTRATE SUPPORT AND PLASMA PROCESSING APPARATUS

(71) Applicant: Tokyo Electron Limited, Tokyo (JP)

(72) Inventors: Yasuhisa KUDO, Miyagi (JP); Atsushi KAWABATA, Miyagi (JP)

(73) Assignee: Tokyo Electron Limited, Tokyo (JP)

(21) Appl. No.: 19/038,729

(22) Filed: Jan. 28, 2025

Related U.S. Application Data
(63) Continuation of application No. PCT/JP2023/025760, filed on Jul. 12, 2023.
(60) Provisional application No. 63/393,497, filed on Jul. 29, 2022.

(51) Int. Cl. H01J 37/32

(52) U.S. Cl. CPC H01J 37/32724; H01J 37/32697; H01J 2237/2001

(57) ABSTRACT

A substrate support includes a first layer, and a second layer disposed on the first layer, including a substrate supporting surface and at least one adsorption electrode, and made of a dielectric material having a volume resistance value higher than a volume resistance value of the first layer. The first layer includes a first region in contact with the second layer and having a first thermal conductivity, a second region having a second thermal conductivity higher than the first thermal conductivity and configured such that the first region is disposed between the second region and the second layer, and a transition region disposed between the first region and the second region and having a thermal conductivity that shifts between the first thermal conductivity and the second thermal conductivity to approach the second thermal conductivity according to an increase in distance from the first region.

### CROSS-REFERENCE TO RELATED APPLICATIONS

This application is a bypass continuation application of international application No. PCT/JP2023/025760 having an international filing date of Jul. 12, 2023 and designating the United States, the international application being based upon and claiming the benefit of priority from U.S. Application No. 63/393,497, filed on Jul. 29, 2022, the entire contents of each are incorporated herein by reference.

### TECHNICAL FIELD

The present disclosure relates to a substrate support and a plasma processing apparatus.

### BACKGROUND

JP2004-031594A discloses a method of manufacturing an electrostatic chuck in which a plurality of ceramic green sheets cut into a predetermined shape are stacked and fired to form a plate-shaped ceramic body such that forming directions thereof are different from each other.

The electrostatic chuck of JP2004-031594A includes a placement surface that holds a substrate on a surface of the plate-shaped ceramic body. The plate-shaped ceramic body is bonded and fixed to a metal base having a cooling structure by an insulating adhesive. Heat generated on a surface of the substrate is released outside a system through a cooling medium as the cooling medium flows in the metal base.

### CITATION LIST

### Patent Documents

Patent Literature 1: JP2004-031594A

### SUMMARY

Exemplary embodiments of the present disclosure provide a technique for efficiently dissipating heat of a substrate and efficiently cooling the substrate.

A substrate support according to one exemplary embodiment includes a first layer, and a second layer disposed on the first layer, including a substrate supporting surface for supporting a substrate and at least one adsorption electrode for adsorbing the substrate, and made of a dielectric material having a volume resistance value higher than a volume resistance value of the first layer, and the first layer includes a first region in contact with the second layer and having a first thermal conductivity, a second region having a second thermal conductivity higher than the first thermal conductivity and having a configuration in which the first region is disposed between the second region and the second layer, and a transition region disposed between the first region and the second region and having a thermal conductivity that shifts within a range between the first thermal conductivity and the second thermal conductivity to approach the second thermal conductivity according to an increase in distance from the first region in a direction from the first region toward the second region.

According to an exemplary embodiment of the present disclosure, heat of a substrate is efficiently dissipated in a heat dissipation path, and thus, the substrate is efficiently cooled.

### BRIEF DESCRIPTION OF DRAWINGS

FIG. 1 is a diagram schematically illustrating a configuration of a plasma processing system according to an exemplary embodiment.

FIG. 2 is a cross-sectional view illustrating an example of a configuration of a plasma processing apparatus according to an exemplary embodiment.

FIG. 3 is a cross-sectional view illustrating an example of a configuration of a substrate support according to an exemplary embodiment.

FIG. 4 is a cross-sectional view illustrating an example of a transition region of the substrate support according to an exemplary embodiment.

FIG. 5 is a cross-sectional view illustrating a configuration of a substrate support according to a first modification example.

FIG. 6 is a cross-sectional view illustrating a configuration of a substrate support according to a second modification example.

FIG. 7 is a cross-sectional view illustrating a configuration of a substrate support according to a third modification example.

FIG. 8 is a cross-sectional view illustrating a configuration of a substrate support according to a fourth modification example.

FIG. 9 is a cross-sectional view illustrating a configuration of a substrate support according to a fifth modification example.

FIG. 10 is a cross-sectional view illustrating a configuration of a substrate support according to a sixth modification example.

### DETAILED DESCRIPTION

Hereinafter, a configuration of a substrate processing apparatus according to an exemplary embodiment will be described with reference to the drawings. The same reference numerals will be given to elements having substantially the same functional configurations throughout the specification, and redundant description thereof will be omitted.

### Plasma Processing System

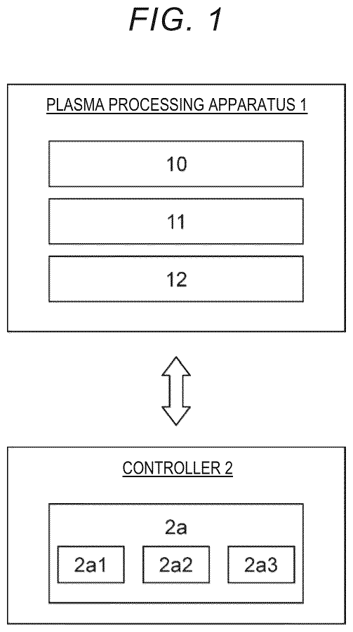

FIG. 1 is a diagram schematically illustrating a configuration of a plasma processing system according to an exemplary embodiment. In one embodiment, the plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supplier 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 200 kHz to 150 MHz.

The controller 2 processes computer-executable instructions for instructing the plasma processing apparatus 1 to execute various steps described in the disclosure. The controller 2 may be configured to control elements of the plasma processing apparatus 1 to execute the various steps described herein. In an embodiment, part or all of the controller 2 may be included in the plasma processing apparatus 1. The controller 2 may include, for example, a computer 2a. For example, the computer 2a may include a processor (central processing unit (CPU)) 2a1, a storage unit 2a2, and a communication interface 2a3. The processor 2a1 may be configured to perform various control operations based on a program stored in the storage unit 2a2. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Plasma Processing Apparatus

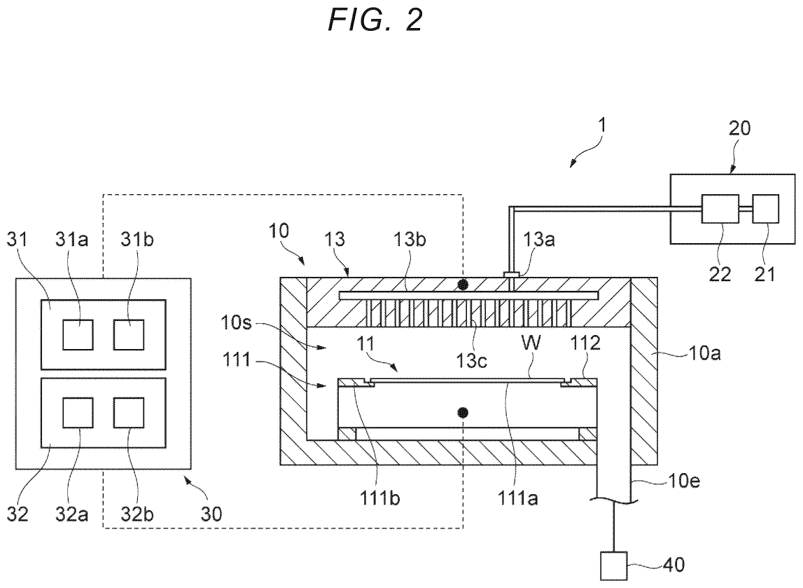

Next, an example of a configuration of a capacitive coupling plasma processing apparatus as an example of the plasma processing apparatus 1 will be described with reference to FIG. 2. The plasma processing apparatus 1 includes the plasma processing chamber 10, the gas supplier 20, a power source 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 forms at least a part of a ceiling portion of the plasma processing chamber 10. The plasma processing chamber 10 has a plasma processing space 10s defined by the shower head 13, a sidewall 10a of the plasma processing chamber 10, and the substrate support 11. The sidewall 10a is grounded. The shower head 13 and the substrate support 11 are electrically insulated from a housing of the plasma processing chamber 10.

The substrate support 11 includes a substrate support 111 and a ring assembly 112. The substrate support 111 has a central region 111a for supporting a substrate (wafer) W and an annular region 111b for supporting the ring assembly 112. The annular region 111b of the substrate support 111 surrounds the central region 111a of the substrate support 111 in a plan view. The substrate W is disposed on a substrate supporting surface 114 in the central region 111a of the substrate support 111, and the ring assembly 112 is disposed on a ring supporting surface of the annular region 111b of the substrate support 111 to surround the substrate W on the substrate supporting surface 114. Details of a configuration of the substrate support 111 will be described below.

The shower head 13 is configured to introduce at least one processing gas from the gas supplier 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. The gas introduction unit may include, in addition to the shower head 13, one or more side gas injectors (SGI) that are attached to one or more openings formed in the sidewall 10a.

The gas supplier 20 may include at least one gas source 21 and at least one flow rate control device 22. In one embodiment, the gas supplier 20 is configured to supply at least one processing gas from the respective corresponding gas sources 21 to the shower head 13 via the respective corresponding flow rate control device 22. The flow rate control device 22 may include, for example, a mass flow controller or a pressure-controlled flow rate control device. Further, the gas supplier 20 may include at least one flow rate modulation device that modulates or pulses a flow rate of at least one processing gas.

The power source 30 includes an RF power source 31 coupled to the plasma processing chamber 10 via at least one impedance matching circuit. The RF power source 31 is configured to supply at least one RF signal (RF power), such as a source RF signal and a bias RF signal, to the conductive member of the substrate support 11 and/or the conductive member of the shower head 13. As a result, plasma is formed from at least one processing gas supplied into the plasma processing space 10s. Accordingly, the RF power source 31 may function as at least a part of the plasma generator 12. Further, supplying of the bias RF signal to the conductive member of the substrate support 11 can generate a bias potential in the substrate W to draw an ion component in the formed plasma to the substrate W.

In one embodiment, the RF power source 31 includes a first RF generator 31a and a second RF generator 31b. The first RF generator 31a is coupled to the conductive member of the substrate support 11 and/or the conductive member of the shower head 13 via at least one impedance matching circuit, and configured to generate a source RF signal (source RF power) for plasma generation. In one embodiment, the source RF signal has a frequency in the range of 13 MHz to 150 MHz. In one embodiment, the first RF generator 31a may be configured to generate a plurality of source RF signals having different frequencies. The generated one or a plurality of source RF signals are supplied to the conductive member of the substrate support 11 and/or the conductive member of the shower head 13. The second RF generator 31b is coupled to the conductive member of the substrate support 11 via at least one impedance matching circuit, and configured to generate a bias RF signal (bias RF power). In one embodiment, the bias RF signal has a lower frequency than the source RF signal. In one embodiment, the bias RF signal has a frequency in the range of 400 kHz to 13.56 MHz. In one embodiment, the second RF generator 31b may be configured to generate a plurality of bias RF signals having different frequencies. The generated one or more bias RF signals are supplied to the conductive member of the substrate support 11. In various embodiments, at least one of the source RF signal and the bias RF signal may be pulsed.

The power source 30 may include a DC power source 32 coupled to the plasma processing chamber 10. The DC power source 32 includes a first DC generator 32a and a second DC generator 32b. In one embodiment, the first DC generator 32a is connected to the conductive member of the substrate support 11 and configured to generate a first DC signal. The generated first DC signal is applied to the conductive member of the substrate support 11. In one embodiment, the first DC signal may be applied to another electrode, such as an electrode in an electrostatic chuck ESC. In one embodiment, the second DC generator 32b is configured to be connected to the conductive member of the shower head 13 and to generate a second DC signal. The generated second DC signal is applied to the conductive member of the shower head 13. In various embodiments, the first and second DC signals may be pulsed. The first DC generator 32a and the second DC generator 32b may be provided in addition to the RF power source 31, or the first DC generator 32a may be provided in place of the second RF generator 31b.

The exhaust system 40 may be connected, for example, to a gas discharge port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### Substrate Support

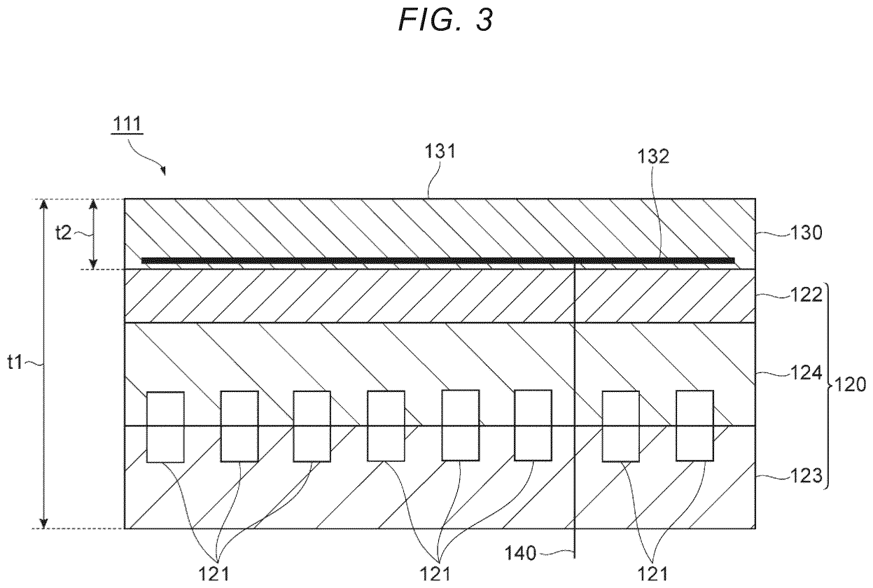

Next, the substrate support 111 according to an exemplary embodiment will be described in detail. FIG. 3 is a cross-sectional view illustrating an example of a configuration of a substrate support according to an exemplary embodiment. FIG. 3 illustrates a part of the central region 111a of the substrate support 111, and omits illustration of the other portions of the central region 111a and the annular region 111b. However, the other portions of the central region 111a and the annular region 111b are also assumed to have the same configurations as the illustrated portion of the central region 111a.

In FIG. 3, the substrate support 111 has a first layer 120 and a second layer 130 disposed on the first layer 120. The second layer 130 includes a substrate supporting surface 131 for supporting the substrate W, and at least one adsorption electrode 132 for adsorbing the substrate W. The substrate support 111 may further have a power supply unit 140 for supplying a power to the adsorption electrode 132. A size of the substrate support 111 is not limited in particular and may be appropriately designed according to a processing target. In one example, a thickness t1 of the substrate support 111 may be 30 mm or less, 28 mm or less, or 25 mm or less.

The first layer 120 has a first region 122, a second region 123, and a transition region 124. The first region 122, the second region 123, and the transition region 124 are aligned in the order of the first region 122, the transition region 124, and the second region 123 in a thickness direction of the first layer 120 from the second layer 130 side. The first region 122 is disposed between the second layer 130 and the second region 123 and is in contact with the second layer 130. The first region 122 is a region having a first thermal conductivity. The first thermal conductivity may be a third thermal conductivity or higher, which is a thermal conductivity of the second layer 130 to be described below. The second region 123 has a second thermal conductivity higher than the first thermal conductivity. The second thermal conductivity may be, for example, 80 W/(m·K) or higher, 100 W/(m·K) or higher, 110 W/(m·K) or higher, or 120 W/(m·K) or higher.

The transition region 124 is disposed between the first region 122 and the second region 123. The transition region 124 has a thermal conductivity that shifts within a range between the first thermal conductivity and the second thermal conductivity such that the thermal conductivity of the transition region 124 approaches the second thermal conductivity according to an increase in distance from the first region 122 in a direction from the first region 122 toward the second region 123. The thermal conductivity of the transition region 124 may change from the first thermal conductivity to the second thermal conductivity according to the increase in distance from the first region 122. The thermal conductivity in the transition region 124 may shift gradually or continuously from the first region 122 toward the second region 123.

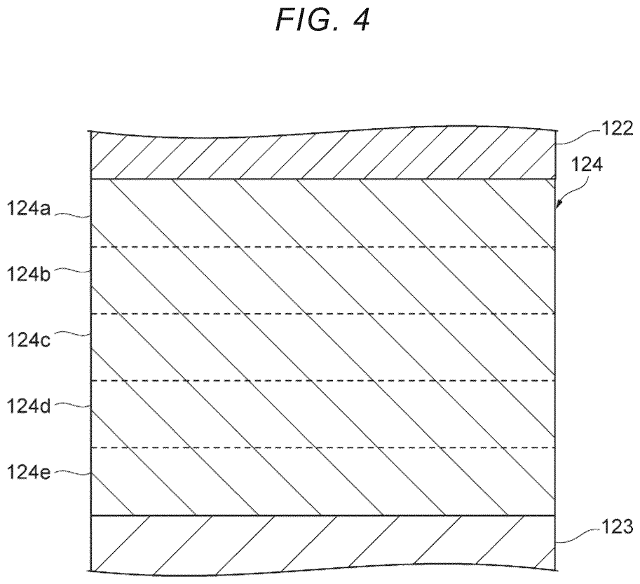

In one embodiment, the transition region 124 may be configured with a plurality of regions. That is, the transition region 124 may have a stack structure that includes a plurality of layers. For example, as illustrated in FIG. 4, the transition region 124 may include a first transition region 124a, a second transition region 124b, a third transition region 124c, a fourth transition region 124d, and a fifth transition region 124e. A thermal conductivity of the first transition region 124a to a thermal conductivity of the fifth transition region 124e may be different from each other. Alternatively, two or more regions adjacent to each other among the first transition region 124a to the fifth transition region 124e may have the same thermal conductivity. In another embodiment, the transition region 124 may be a single layer.

In either embodiment, the thermal conductivity of the transition region 124 may shift gradually or continuously from the first region 122 toward the second region 123. Further, in either embodiment, the transition region 124 may have the same thermal conductivity as or different from the first thermal conductivity in a portion (for example, the first transition region 124a) in contact with the first region 122. Further, in either embodiment, the transition region 124 may have the same thermal conductivity as or different from the second thermal conductivity in a portion (for example, the fifth transition region 124e) in contact with the second region 123.

A line expansion coefficient of the second region 123 is different from a line expansion coefficient of the second layer 130. The first region 122 and the transition region 124 have line expansion coefficients between the line expansion coefficient of the second layer 130 and the line expansion coefficient of the second region 123. The line expansion coefficients of the first region 122 and the transition region 124 may shift to approach the line expansion coefficient of the second region 123 according to an increase in distance from the second layer 130 in a direction from the second layer 130 toward the second region 123. The line expansion coefficient of the first region 122 may be the same as or different from the line expansion coefficient of the second layer 130. Further, the line expansion coefficient of the transition region 124 may be the same as or different from the line expansion coefficient of the first region 122 in the portion in contact with the first region 122. Further, the line expansion coefficient of the transition region 124 may be the same as or different from the line expansion coefficient of the second region 123 in the portion in contact with the second region 123. For example, when the line expansion coefficient of the second region 123 is less than the line expansion coefficient of the second layer 130, the line expansion coefficient of the first region 122 may be the same as the line expansion coefficient of the second layer 130 or less than the line expansion coefficient of the second layer 130. In this case, the line expansion coefficient of the transition region 124 gradually decreases as a distance from the first region 122 increases.

The first layer 120 is formed of a material with a high thermal conductivity. The second region 123 may contain at least one selected from the group consisting of a high thermal conductivity ceramic such as aluminum nitride (AlN), a metal matrix composite (MMC), a first metal, and an alloy including the first metal. The metal matrix composite may include at least one selected from a group consisting of a composite of silicon and aluminum (Si—Al composite), a composite of silicon carbide and aluminum (SiC—Al composite), and a composite of silicon and titanium (Si—Ti composite). The first metal may include at least one selected from the group consisting of titanium (Ti), molybdenum (Mo), tungsten (W), and tantalum (Ta). The first region 122 and the transition region 124 may be formed of the same material as the second region 123. However, as described above, characteristics (composition or composition ratio) of a material may be changed such that the thermal conductivities and line expansion coefficients of the first region 122 and the transition region 124 are different from the thermal conductivity and line expansion coefficient of the second region 123.

As illustrated in FIG. 3, the first layer 120 may include a flow path 121 for adjusting temperatures of the substrate W, the ring assembly 112, and the substrate support 111. The flow path 121 may extend in an in-plane direction (a direction perpendicular to a thickness direction of the first layer 120) of the substrate W. The flow path 121 is connected to a temperature control module such as a chiller. A temperature control medium such as brine may be supplied from a chiller to the flow path 121. The flow path 121 may be formed such that at least a part of the flow path 121 is included in the transition region 124. In the example of FIG. 3, the flow path 121 is disposed across the transition region 124 and the second region 123. Alternatively, the flow path 121 may be formed such that an entirety of the flow path 121 is included in the transition region 124.

The second layer 130 may be made of dielectric material. The material of second layer 130 may have a volume resistance value that is higher than a volume resistance value of the material of the first layer 120. The second layer 130 may be formed of, for example, a ceramic material with volume resistivity of 1×10¹⁵ Ω or more in an inclusive temperature range that extends from room temperature through, and including, 350° C. More particularly, the ceramic material of the second layer may have a volume resistivity of 1×10¹⁶ Ω or more at a same temperature range. As an example, the second layer 130 may be formed of high-purity alumina (aluminum oxide), such as material including alumina of, for example, 99.5 mass % or more. Further, a porosity of the second layer 130 may be 0.5% or less, such as 0.3% or less, or even 0.1% or less. As an exemplary bottom end of the porosity range, the porosity of the second layer 130 may be 0.01% or more. In this context, the porosity is a value indicating a ratio of pores (voids) included in a corresponding cross-section to an area of the corresponding cross-section when the second layer 130 is observed in a cross section.

Each of the first region 122 and the transition region 124 includes a material (a first material) included in the second region 123 and a material (a second material) included in the second layer 130. Each of the first region 122 and the transition region 124 has a gradient composition. The gradient composition is a material composition in which a ratio of the first material to the second material increases according to an increase in distance from the second layer 130 in a direction from the second layer 130 toward the second region 123. For example, when the first material includes aluminum nitride and the second material includes alumina, a ratio of the aluminum nitride to the alumina gradually increases according to an increase in distance from the second layer 130 in a direction from the second layer 130 toward the second region 123. In this case, line expansion coefficients of the first region 122 and the transition region 124 shift to approach a line expansion coefficient of the second region 123 according to the increase in the distance from the second layer 130 in the direction from the second layer 130 toward the second region 123.

As described above, the second layer 130 is disposed on the first layer 120 and includes the substrate supporting surface 131 for supporting the substrate W, and at least one adsorption electrode 132 for adsorbing the substrate W. The substrate supporting surface 131 may include a plurality of dots (not illustrated). That is, the second layer 130 may include a plurality of dot-shaped convex portions. In this case, the substrate support 111 may support the substrate W with upper surfaces of the plurality of dots (or the plurality of convex portions). A gap may be formed between a back surface of the substrate W and the substrate supporting surface 131 by the plurality of dots. The substrate support 111 may be configured to supply a heat transfer gas that transfers heat between the substrate W and the substrate support 111 to the gap. The heat transfer gas is, for example, a helium gas (He gas).

The adsorption electrode 132 is formed of a conductor such as a metal. The adsorption electrode 132 may be a single electrode or may be a plurality of electrodes. In one example, the adsorption electrode 132 is configured with two electrodes, and a DC voltage is applied to generate a potential difference between the two electrodes. Instead of a DC power source, an AC power source may be connected to the adsorption electrode 132. A distance (thickness) t2 from a surface of the second layer 130 to an upper surface of the adsorption electrode 132 may be, for example, 0.5 mm or less. The first layer 120 may include another electrode in addition to or instead of the adsorption electrode 132. The other electrode may be a heater electrode for heating the substrate W and/or a bias electrode for attracting ions to the substrate W.

The second layer 130 has a third thermal conductivity that is less than or equal to the first thermal conductivity. The third thermal conductivity may be equal to or substantially equal to the first thermal conductivity. The third thermal conductivity may be, for example, 50 W/(m·K) or less, 40 W/(m·K) or less, or 30 W/(m·K) or less.

In the substrate support 111 described above, the second layer 130 has a higher volume resistance value than the first layer 120, and accordingly, a high adsorption force of the substrate W is ensured in the second layer 130 that is an adsorption layer. The second layer 130 is in contact with the first region 122 of the first layer 120 without using an adhesive, and is thermally connected to the first layer 120 without using an adhesive with high thermal resistance. Further, in the first layer 120, the thermal conductivity gradually increases from the first region 122 in contact with the second layer 130 toward the second region 123. That is, in the first layer 120, the thermal resistance gradually decreases from the first region 122 toward the second region 123. Therefore, heat of the substrate W on the second layer 130 is efficiently dissipated in a heat dissipation path from the first region 122 toward the second region 123. Accordingly, the substrate W on the substrate support 111 is efficiently cooled.

Further, the first layer 120 in the substrate support 111 has the transition region 124 described above. Therefore, thermal resistance in the substrate support 111 is reduced, and the substrate W can be cooled to a cryogenic temperature range. For example, the substrate support 111 of the present embodiment can cool the substrate W to −50° C. or less, −100° C. or less, or −200° C. or less. Further, when the second layer 130 is formed of a material with high plasma resistance, for example, high-purity alumina, the second layer 130 has high resistance to plasma and can suppress generation of particles or the like.

Further, as described above, the line expansion coefficients of the first region 122 and the transition region 124 may shift to approach the line expansion coefficient of the second region 123 according to an increase in distance from the second layer 130 in a direction from the second layer 130 toward the second region 123. In this case, even when the substrate support 111 is heated by heat input from plasma during plasma processing, warping and cracking of the second layer 130 caused by a difference between the line expansion coefficient of the first layer 120 and the line expansion coefficient of the second layer 130 are suppressed.

Further, the first layer 120 may include the flow path 121 through which a refrigerant is circulated. In this case, a temperature of the substrate W on the second layer 130 may be adjusted by heat exchange between the refrigerant and the first layer 120.

Further, the first thermal conductivity of the first region 122 of the first layer 120 may be equal to or higher than the thermal conductivity of the second layer 130. In this case, heat of the substrate W on the second layer 130 is more efficiently transferred from the second layer 130 toward the second region 123 via the first region 122.

### Method of Manufacturing Substrate Support

The substrate support 111 of the exemplary embodiment is not limited in particular and may be manufactured by various methods. In one example, the method of manufacturing the substrate support 111 includes a process of forming the first layer 120, a process of forming the second layer 130, and a process of bonding the first layer 120 to the second layer 130. The first layer 120 may be formed by, for example, a green sheet method. The second layer 130 may be formed by, for example, a hot pressing method. The first layer 120 and the second layer 130 may be bonded to each other through, for example, metal bonding, diffusion bonding, or the like.

The substrate support 111 of the exemplary embodiment may be integrally molded. For example, a method of manufacturing the substrate support 111 may include a process of forming a compression-molded body of high-purity ceramic powder, a process of forming the adsorption electrode 132, a process of forming a stack body in which ceramic green sheets are stacked, and a process of sintering an unsintered body obtained by stacking the stack body, the adsorption electrode 132, and the compression-molded body in this order while pressing the unsintered body. The process of forming the second layer 130 described above may include a process of forming the compression-molded body of high-purity ceramic powder. In this case, as illustrated in FIG. 3, the adsorption electrode 132 may be included in the compression-molded body of the high-purity ceramic powder. In this case, in the process of forming the second layer 130, a portion of the second layer 130 closer to the substrate supporting surface 131 than the adsorption electrode 132 may be formed by the compression-molded body of a high-purity ceramic powder, and the adsorption electrode 132 may be formed by printing on a surface of the compression-molded body. Then, another compression-molded body of the high-purity ceramic powder may be formed, and another compression-molded body and the compression-molded body on which the adsorption electrode 132 is printed may be bonded together such that the adsorption electrode 132 is sandwiched therebetween.

Alternatively, the method of manufacturing the substrate support 111 may include a process of forming a high-purity ceramic compression-molded body having the adsorption electrodes 132, a process of forming a stack body in which ceramic green sheets are stacked, and a process of sintering an unsintered body in which the compression-molded body and the stack body are stacked while pressing the unsintered body. The process of forming the second layer 130 described above may include a process of forming a high-purity ceramic compression-molded body having the adsorption electrode 132. In this case, in the process of forming the second layer 130, the adsorption electrode 132 is printed on a surface of the high-purity ceramic compression-molded body.

The process of forming the first layer 120 described above may include a process of forming a stack body in which ceramic green sheets are stacked. That is, the first layer 120 may be formed as the stack body in which the ceramic green sheets are stacked. Alternatively, the first layer 120 may be formed as a single layer. When the first layer 120 is formed as a single layer, the first layer 120 is formed by, for example, a three-dimensional (3D) printer or the like.

The process of bonding the first layer 120 and the second layer 130 described above may include the process of sintering described above. In this process, the unsintered body described above may be sintered while being pressed.

In the method of manufacturing the substrate support 111 described above, holes may be formed in the first layer 120 and the second layer 130. Further, the power supply unit 140 may be formed to connect the adsorption electrode 132 to the DC power source 32 through the holes. Further, the power supply unit 140 may be integrally formed with the first layer 120 and the second layer 130. For example, the second layer 130 may be formed such that a part of the adsorption electrode 132 is exposed. Then, when the first layer 120 is stacked and formed by a 3D printer, the power supply unit 140 may be formed by stacking and forming a conductor such as a metal such that the exposed adsorption electrode 132 and the DC power source 32 are connected to each other.

Further, when the second layer 130 in the substrate support 111 of the exemplary embodiment is worn or damaged, only the second layer 130 may be replaced. For example, the worn second layer 130 may be removed through peeling, grinding, or the like, and a new second layer 130 may be bonded to the first layer 120.

### Plasma Processing Method

Next, a plasma processing method using the plasma processing apparatus 1 including the substrate support 111 configured as described above will be described. For example, etching processing and/or layer formation processing are performed as plasma processing.

In the plasma processing method, first, the substrate W is loaded into the plasma processing chamber 10, and the substrate W is placed on the substrate supporting surface 131. Thereafter, pressure in the plasma processing chamber 10 is reduced to a desired vacuum level by the exhaust system 40, and a DC voltage is applied to the adsorption electrode 132. Thereby, a Coulomb force is generated between the adsorption electrode 132 and the substrate W, and the substrate W is electrostatically adsorbed (or attracted) to the substrate supporting surface 131.

Next, a processing gas is supplied from the gas supplier 20 to the plasma processing space 10s through the shower head 13. Further, source RF power for generating plasma is supplied to a conductive member of the substrate support 11 and/or a conductive member of the shower head 13 by the first RF generator 31a of the RF power source 31, and thereby, the processing gas is excited, and plasma is generated. At this time, the second RF generator 31b may supply a bias RF signal for attracting ions. In the plasma processing method, plasma processing is performed for the substrate W by an action of the generated plasma. The plasma processing method described above can be performed by controlling respective configurations of the plasma processing apparatus 1 by the controller 2 to perform desired processes.

Next, some modification examples of the exemplary embodiment will be described. Since basic configurations and operations of the following modification examples are the same as the configuration and operation of the above-described embodiment, overlapping configurations and operations will be omitted or simplified, and only different configurations and operations will be described.

### First Modification Example

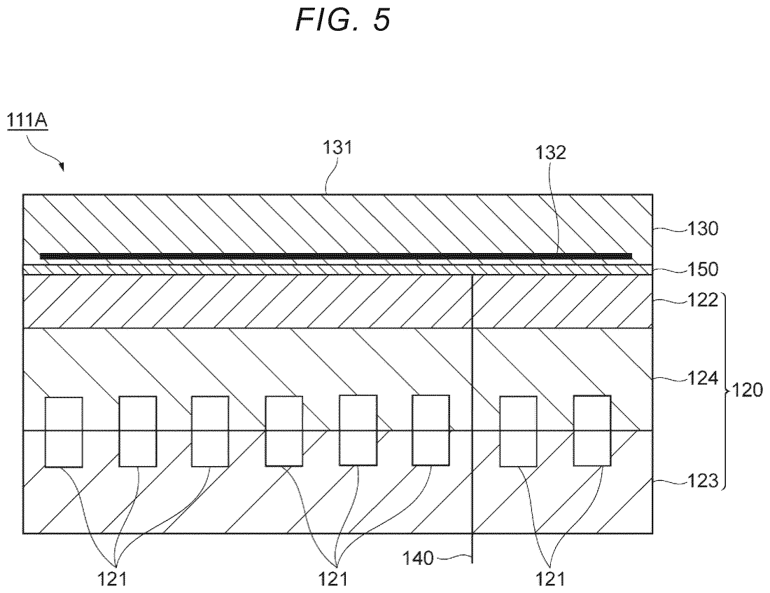

FIG. 5 is a cross-sectional view schematically illustrating a configuration of a substrate support according to a first modification example. A substrate support 111A illustrated in FIG. 5 further includes a diffusion prevention layer 150 provided between a first layer 120 and a second layer 130. The diffusion prevention layer 150 suppresses diffusion of constituent components of the first layer 120 into the second layer 130. The diffusion prevention layer 150 may be formed of the same material as the second layer 130.

The substrate support 111A suppresses the diffusion of the constituent components of the first layer 120 into the second layer 130 and suppresses a decrease of a volume resistance value of the second layer 130. Thereby, it is possible to suppress a decrease in electrostatic adsorption force between the substrate W and the adsorption electrode 132 over time. Further, when the diffusion prevention layer 150 is formed of the same material as the second layer 130, a thermal conductivity of the substrate support 111A increases in a direction from the second layer 130 toward the second region 123 of the first layer 120. Therefore, heat of the substrate W on the second layer 130 is efficiently dissipated from the second layer 130 toward the second region 123. Accordingly, the substrate W on the substrate support 111A is efficiently cooled.

### Second Modification Example

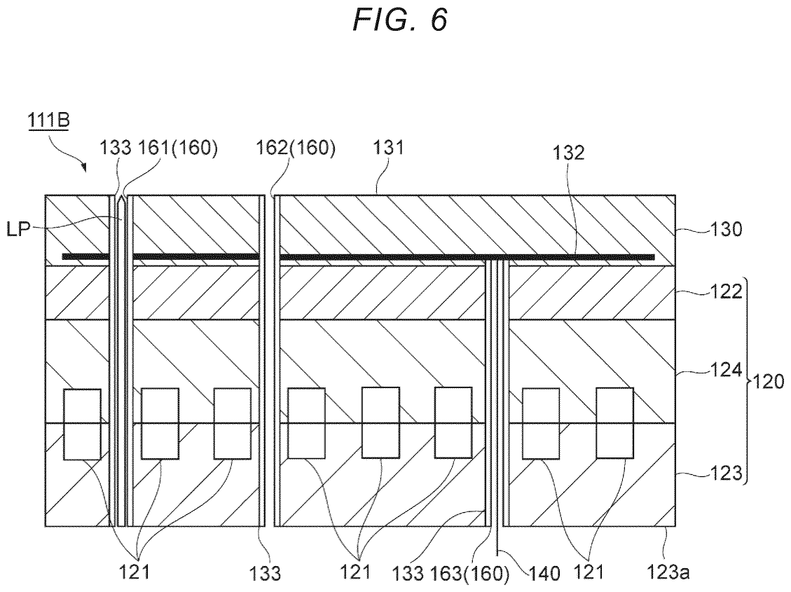

FIG. 6 is a cross-sectional view schematically illustrating a configuration of a substrate support according to a second modification example. A substrate support 111B illustrated in FIG. 6 further includes at least one tube 133 made of an insulating material. In the illustrated example, the substrate support 111B further includes a plurality of tubes 133. Similarly to the substrate support 111, a second region 123 in the substrate support 111B has a bottom surface 123a opposite to a substrate supporting surface 131. The plurality of tubes 133 respectively define holes 160. The plurality of tubes 133 define a hole 161, a hole 162, and a power supply hole 163 as the holes 160. The holes 161 and 162 penetrate the first layer 120 and the second layer 130 from the bottom surface 123a toward the substrate supporting surface 131. The power supply hole 163 extends from the bottom surface 123a to an adsorption electrode 132. A power supply unit 140 may be formed in the substrate support 111B to connect the adsorption electrode 132 to a DC power source 32 through the power supply hole 163. Each of the plurality of tubes 133 may be formed of the same insulating material as the material of the second layer 130. Each of the plurality of tubes 133 may be integrally formed with the second layer 130. The hole 161 may be a pin hole through which a lift pin LP moves up and down. The hole 162 may be a gas supply hole for supplying a heat transfer gas such as helium between the substrate W and the substrate supporting surface 131.

According to the substrate support 111B, the tube 133 defining the hole 160 may be formed of the same material as the second layer 130 having high plasma resistance. Thereby, discharge resistance and the plasma resistance of the tube are ensured. In addition, it is not necessary to insert a sleeve made of an insulating material into the hole 160. However, from a viewpoint or so on of narrowing a radial space of the hole 160 and preventing abnormal discharge, a sleeve made of an insulating material may be inserted into the hole 160 separately.

### Third Modification Example to Fifth Modification Example

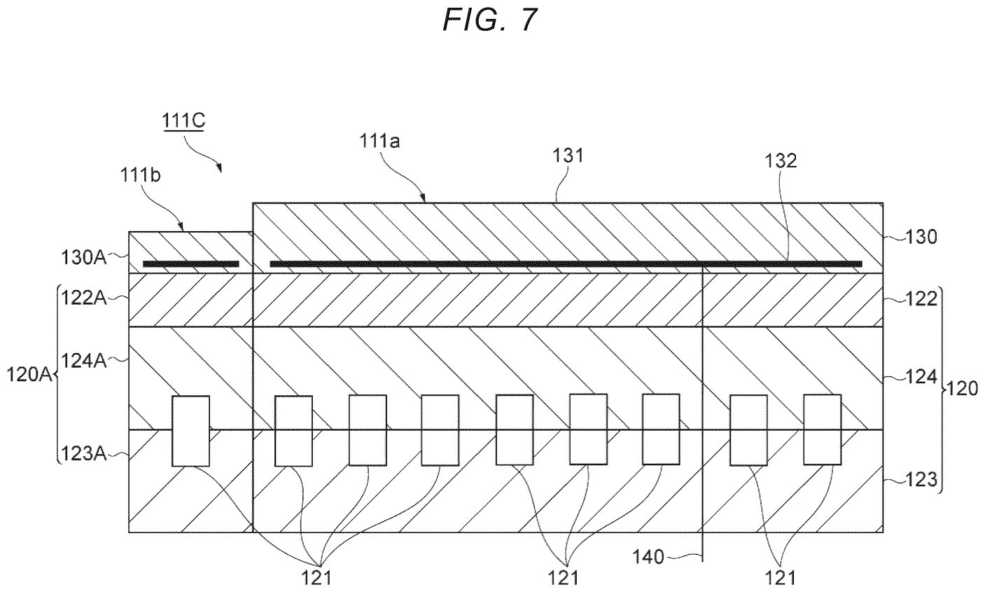

FIG. 7 to FIG. 9 are cross-sectional views schematically illustrating configurations of a substrate support according to a third modification example, a substrate support according to a fourth modification example, and a substrate support according to a fifth modification example.

An annular region 111b of a substrate support 111C illustrated in FIG. 7 has the same configuration as a central region 111a. The annular region 111b of the substrate support 111C includes a third layer 120A and a fourth layer 130A disposed on the third layer 120A. A configuration of the third layer 120A is the same as a configuration of a first layer 120, and a configuration of the fourth layer 130A is the same as a configuration of a second layer 130. The fourth layer 130A is made of a dielectric material having higher volume resistance value than the third layer 120A. The third layer 120A includes a third region 122A, a fourth region 123A, and a transition region 124A. A configuration of the third region 122A is the same as a configuration of a first region 122, and a configuration of the fourth region 123A is the same as a configuration of a second region 123. A configuration of the transition region 124A is the same as a configuration of a transition region 124 in the central region 111a. That is, the third region 122A is provided on a fourth layer 130A side and has a first thermal conductivity. The third region 122A is disposed between the fourth region 123A and the fourth layer 130A. The fourth region 123A has a second thermal conductivity higher than the first thermal conductivity.

The transition region 124A is disposed between the third region 122A and the fourth region 123A. The transition region 124A has a thermal conductivity that shifts within a range between the first thermal conductivity and the second thermal conductivity to approach the second thermal conductivity according to an increase in distance from the third region 122A in a direction from the third region 122A toward the fourth region 123A. Thermal resistance of the third layer 120A in the substrate support 111C gradually decreases from the third region 122A toward the fourth region 123A. Therefore, heat of a ring assembly 112 on the fourth layer 130A is efficiently dissipated from the third region 122A toward the fourth region 123A. Accordingly, the ring assembly 112 in the substrate support 111C is efficiently cooled. As illustrated in FIG. 7, the annular region 111b of the substrate support 111C may be integrally formed with, or in contact with, the central region 111a.

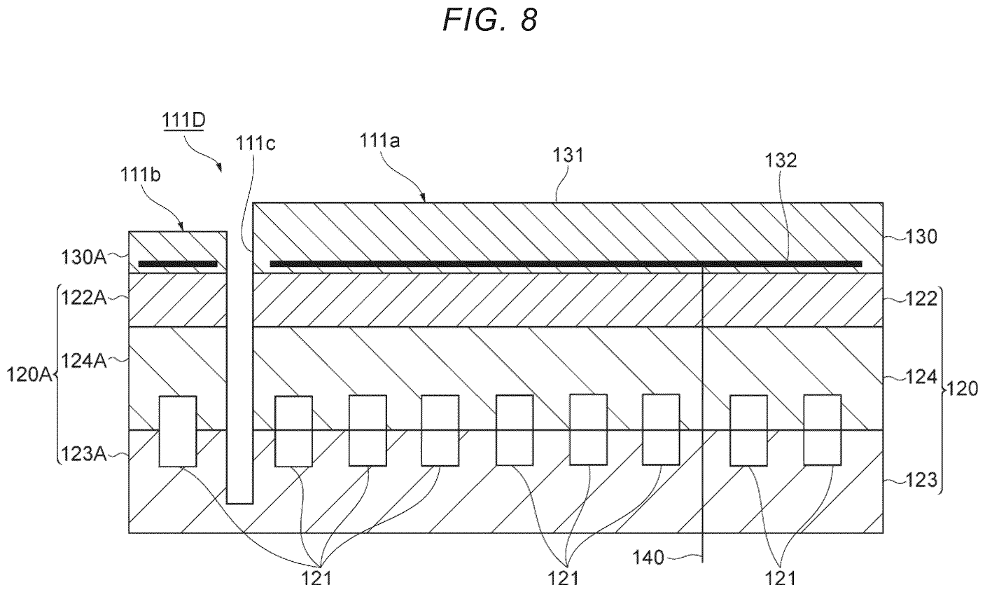

A substrate support 111D illustrated in FIG. 8 has a groove 111c between a central region 111a and an annular region 111b. The groove 111c may spatially separate a second layer 130 from a fourth layer 130A. The groove 111c may spatially separate a first region 122 from a third region 122A. The groove 111c may spatially separate a transition region 124 of the central region 111a from a transition region 124A of the annular region 111b. The groove 111c may spatially separate a part of a second region 123 from a part of a fourth region 123A. The second region 123 may be connected to the fourth region 123A between a bottom surface of the groove 111c and a bottom surface of the substrate support 111D. The substrate support 111D exhibits the same effect as an effect of the substrate support 111C. In addition, the substrate support 111D can suppress transfer of heat between the central region 111a and the annular region 111b and can adjust a thermal conduction in the central region 111a and the annular region 111b independently of each other.

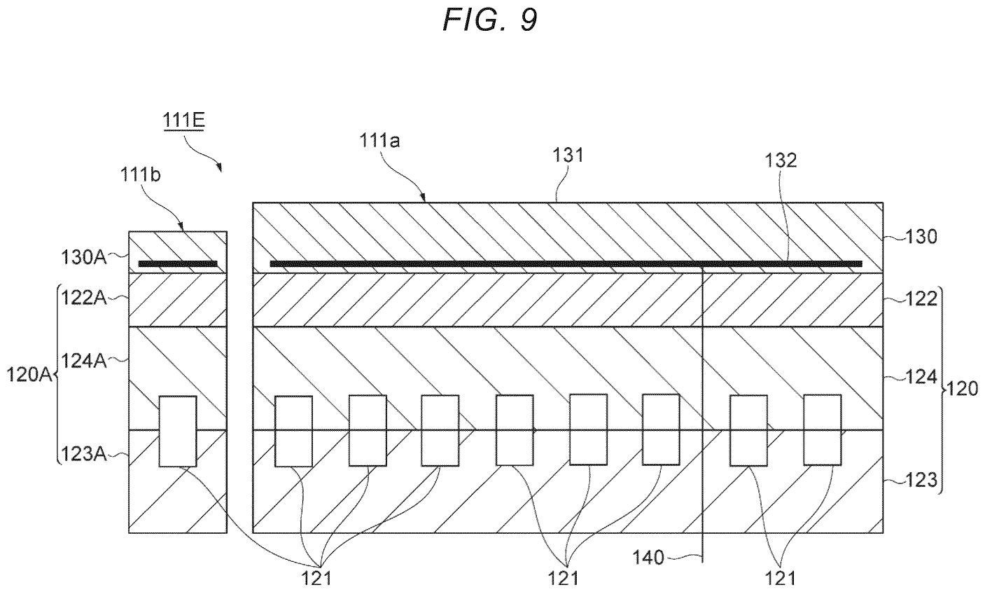

In a substrate support 111E illustrated in FIG. 9, a central region 111a and an annular region 111b are completely separated from each other. In the substrate support 111E, the central region 111a and the annular region 111b may be separately formed. The substrate support 111E exhibits the same effect as the effect of the substrate support 111D. In addition, a degree of freedom of manufacturing the central region 111a and the annular region 111b in the substrate support 111E is improved.

### Sixth Modification Example

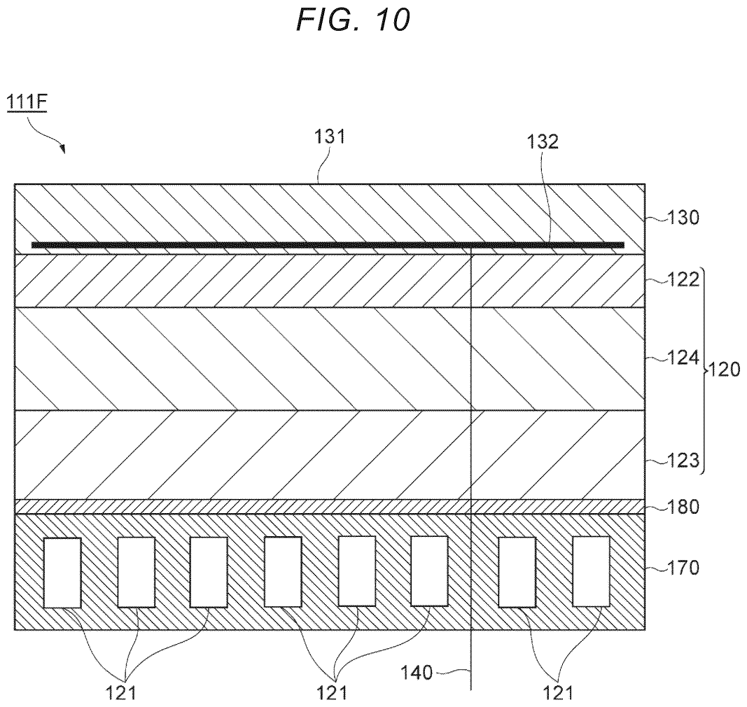

FIG. 10 is a cross-sectional view schematically illustrating a configuration of a substrate support according to a sixth modification example. A substrate support 111F illustrated in FIG. 10 is different from the substrate support 111 in that a first layer 120 and a second layer 130 are on a base 170.

The base 170 supports the first layer 120. The first layer 120 is disposed over the base 170 with a bonding layer 180 interposed therebetween. The base 170 may be made of aluminum. The base 170 may also be made of silicon carbide (SiC). Alternatively, the base 170 may be formed of a metal matrix composite (MMC). The base 170 may include a flow path 121 through which a temperature control medium (for example, a refrigerant) is circulated. In the substrate support 111F, the flow path 121 may be formed in the base 170, instead of the first layer 120. The base 170 and the first layer 120 may be bonded to each other by the bonding layer 180. The bonding layer 180 is interposed between the first layer 120 and the base 170, and connects the first layer 120 to the base 170. The bonding layer 180 may include an organic adhesive component and a filler with a thermal conductivity higher than a thermal conductivity of the organic adhesive component.

The first layer 120 in the substrate support 111F may be formed of, for example, a composite including alumina (Al₂O₃) and AlN. The first layer 120 may include a plurality of layers in which ratios between Al₂O₃ and AlN are different from each other. The plurality of layers in the substrate support 111F correspond to a transition region 124. Similarly to the substrate support 111, the transition region 124 of the substrate support 111F may have a stack structure including a plurality of layers. The transition region 124 may include a first transition region 124a to a fifth transition region 124e. In the transition region 124, a ratio between Al₂O₃ and AlN may be adjusted such that a line expansion coefficient decreases from the second layer 130 toward the base 170. Table 1 shows an example of a ratio (ratio of Al₂O₃ to AlN) of a mass of Al₂O₃ to a mass of AlN in the first layer 120 (the transition region 124), the second layer 130, and the base 170, and line expansion coefficients.

TABLE 1

| | | Constituent | Al₂O₃ to | Line expansion |
|---|---|---|---|---|
| | | material | AlN ratio | coefficient (/° C.) |
| Second layer 130 | | Al₂O₃ | — | 7.2 |
| Transition | 124a | Al₂O₃/AlN | 80/20 | 6.68 |
| region 124 | 124b | Al₂O₃/AlN | 60/40 | 6.16 |
| | 124c | Al₂O₃/AlN | 40/60 | 5.64 |
| | 124d | Al₂O₃/AlN | 20/80 | 5.12 |
| | 124e | Al₂O₃/AlN | 0/100 | 4.6 |

| | | | |
|---|---|---|---|
| Base 170 | SiC | — | 3.7 |

The substrate support 111F may be manufactured by bonding the first layer 120, the second layer 130, and the base 170. That is, a method of manufacturing the substrate support 111F may include a process of manufacturing the first layer 120, a process of manufacturing the second layer 130, and a process of bonding the first layer 120, the second layer 130, and the base 170. In the process of manufacturing the first layer 120, a plurality of ceramic green sheets having different compositions may be formed by a tape molding method, and the first layer 120 may be manufactured by firing and hot isostatic pressing (HIP) a stack body in which the ceramic green sheets are stacked. In the process of manufacturing the second layer 130, the second layer 130 may be manufactured by molding high-purity ceramic powder by a hot pressing method. In the bonding process, the first layer 120 and the second layer 130 may be bonded to each other by using an inorganic bonding material. In the bonding process, the first layer 120 and the base 170 may be bonded to each other by the bonding layer 180 including an organic adhesive component and a filler. Alternatively, the first layer 120 and the base 170 may be brazed with a metal braze such as aluminum.

In the substrate support 111F, it is possible to suppress warping and damage of the substrate support 111F caused by a difference in line expansion coefficient. Further, for example, when the first layer 120 and the base 170 are bonded to each other by the bonding layer 180 including an organic adhesive component and a filler having a thermal conductivity higher than a thermal conductivity of the organic adhesive component or the bonding layer 180 such as a metal braze, thermal conduction from the first layer 120 to the base 170 is performed through the bonding layer 180. Thereby, the thermal conductivity of the substrate support 111F may be improved.

It shall be understood that the embodiments disclosed herein are illustrative and are not restrictive in all aspects. The embodiment described above may be omitted, replaced, or modified in various forms without departing from the scope and spirit of the appended claims.

Hereinafter, various exemplary embodiments included in the present disclosure will be described in [E1] to [E20].

### E1

A substrate support including:

a first layer; and

a second layer disposed on the first layer, including a substrate supporting surface for supporting a substrate and at least one adsorption electrode for adsorbing the substrate, and made of a dielectric material having a volume resistance value higher than a volume resistance value of the first layer,

in which the first layer includes:

a first region in contact with the second layer and having a first thermal conductivity;

a second region having a second thermal conductivity higher than the first thermal conductivity and having a configuration in which the first region is disposed between the second region and the second layer; and

a transition region disposed between the first region and the second region and having a thermal conductivity that shifts within a range between the first thermal conductivity and the second thermal conductivity to approach the second thermal conductivity according to an increase in distance from the first region in a direction from the first region toward the second region.

### E2

The substrate support according to E1,

in which the second layer has a line expansion coefficient different from a line expansion coefficient of the second region,

each of the first region and the transition region has a line expansion coefficient between the line expansion coefficient of the second layer and the line expansion coefficient of the second region, and

the line expansion coefficients of the first region and the transition region shift to approach the line expansion coefficient of the second region according to an increase in distance from the second layer in a direction from the second layer toward the second region.

### E3

The substrate support according to [E1] or [E2], in which the first layer includes a flow path through which a refrigerant is circulated.

### E4

The substrate support according to E3, in which the transition region includes at least a part of the flow path.

### E5

The substrate support according to E3, in which the transition region includes an entirety of the flow path.

### E6

The substrate support according to any one of [E1] to [E5], in which the second region contains at least one selected from the group consisting of aluminum nitride, a metal matrix composite, a composite of silicon and aluminum, a composite of silicon carbide and aluminum, a composite of silicon and titanium, a first metal, and an alloy including the first metal.

### E7

The substrate support according to E6, in which the first metal includes at least one selected from the group consisting of titanium, molybdenum, tungsten, and tantalum.

### E8

The substrate support according to any one of [E1] to [E7], in which the second layer has a third thermal conductivity, and the first thermal conductivity is equal to or higher than the third thermal conductivity.

### E9

The substrate support according to any one of [E1] to [E8], in which the second thermal conductivity is 100 W/(m·K) or higher.

### E10

The substrate support according to any one of [E1] to [E9],

in which the transition region has a stack structure including a plurality of layers, and

the thermal conductivity of the transition region gradually shifts from the first region toward the second region.

### E11

The substrate support according to any one of [E1] to [E10],

in which the transition region is a single layer, and

the thermal conductivity of the transition region continuously shifts from the first region toward the second region.

### E12

The substrate support according to any one of [E1] to [E11], in which the second layer is formed of a ceramic material having a volume resistivity of 1×10¹⁵ Ω or more at a temperature equal to or higher than a room temperature and equal to or lower than 350° C.

### E13

The substrate support according to any one of [E1] to [E12], in which a thermal conductivity of the second layer is 50 W/(m·K) or less.

### E14

A substrate support including:

a first layer;

a second layer disposed on the first layer, including a substrate supporting surface for supporting a substrate and at least one adsorption electrode for adsorbing the substrate, and made of a dielectric material having a volume resistance value higher than a volume resistance value of the first layer; and

a diffusion prevention layer provided between the first layer and the second layer and formed of a material which is same as a material of the second layer,

in which the first layer includes:

a first region in contact with the diffusion prevention layer and having a first thermal conductivity;

a second region having a second thermal conductivity higher than the first thermal conductivity and having a configuration in which the first region is disposed between the second region and the second layer; and

a transition region disposed between the first region and the second region and having a thermal conductivity that shifts within a range between the first thermal conductivity and the second thermal conductivity to approach the second thermal conductivity according to an increase in distance from the first region in a direction from the first region toward the second region.

### E15

The substrate support according to any one of [E1] to [E14],

in which the second region has a bottom surface opposite to the substrate supporting surface,

the substrate support further includes a tube defining holes penetrating the first layer and the second layer from the bottom surface toward the substrate supporting surface, and

the tube is formed of an insulating material which is the same as the material of the second layer.

### E16

The substrate support according to any one of [E1] to [E15],

in which the second region has a bottom surface opposite to the substrate supporting surface,

the substrate support further includes a tube defining power supply holes each extending from the bottom surface to the adsorption electrode, and

the tube is formed of an insulating material which is the same as the material of the second layer.

### E17

The substrate support according to any one of [E1] to E16], further including

an annular region surrounding a central region radially outside the central region including the first layer and the second layer,

the annular region includes a third layer, and a fourth layer disposed on the third layer and made of a dielectric material having a volume resistance value higher than a volume resistance value of the third layer, and

the third layer includes

a third region provided on a side of the fourth layer and having the first thermal conductivity,

a fourth region having the second thermal conductivity higher than the first thermal conductivity and having a configuration in which the third region is disposed between the fourth region and the fourth layer, and

a transition region disposed between the third region and the fourth region and having a thermal conductivity that shifts within a range between the first thermal conductivity and the second thermal conductivity to approach the second thermal conductivity according to an increase in distance from the third region in a direction from the third region toward the fourth region.

### E18

The substrate support according to [E17], in which a groove is formed between the central region and the annular region.

### E19

The substrate support according to [E1] or [E14], further including:

a base including a flow path for circulating a refrigerant and configured to support the first layer; and

a bonding layer interposed between the first layer and the base and configured to connect the first layer to the base,

in which the bonding layer contains an organic adhesive component and a filler having a thermal conductivity higher than a thermal conductivity of the organic adhesive component.

### E20

A substrate support including:

a first layer; and

a second layer disposed on the first layer and including a substrate supporting surface for supporting a substrate and at least one adsorption electrode for adsorbing the substrate,

in which the first layer includes a first region, a transition region, and a second region, the first region is in contact with the second layer and is disposed between the second region and the second layer, the transition region is disposed between the first region and the second region, the second region is formed of a first material including at least one selected from the group consisting of aluminum nitride, a metal matrix composite, a composite of silicon and aluminum, a composite of silicon carbide and aluminum, a composite of silicon and titanium, a first metal, and an alloy including the first metal,

the second layer is formed of a second material including alumina having 99.5 mass % or more, and

the first region and the transition region respectively include the first material and the second material and have a gradient composition in which a ratio of the first material to the second material increases according to an increase in distance from the second layer in a direction from the second layer toward the second region.

### E21

The substrate support according to [E20], in which the first metal includes at least one selected from the group consisting of titanium, molybdenum, tungsten, and tantalum.

### E22

A plasma processing apparatus including:

a chamber; and

the substrate support according to any one of [E1] to [E21], which is disposed in the chamber.

1. A substrate support comprising:
a first layer; and
a second layer disposed on the first layer, including a substrate supporting surface for supporting a substrate and at least one adsorption electrode that controllably attracts the substrate, and made of a dielectric material having a volume resistance value higher than a volume resistance value of the first layer,
wherein the first layer includes:
a first region in contact with the second layer and having a first thermal conductivity;
a second region having a second thermal conductivity higher than the first thermal conductivity and having a configuration in which the first region is disposed between the second region and the second layer; and
a transition region disposed between the first region and the second region and having a thermal conductivity that shifts within a range between the first thermal conductivity and the second thermal conductivity, and progressively approaches the second thermal conductivity according to an increase in distance from the first region in a direction from the first region toward the second region.

2. The substrate support according to claim 1,
wherein the second layer has a line expansion coefficient different from a line expansion coefficient of the second region,
each of the first region and the transition region has a line expansion coefficient between the line expansion coefficient of the second layer and the line expansion coefficient of the second region, and
the line expansion coefficients of the first region and the transition region shift to approach the line expansion coefficient of the second region according to an increase in distance from the second layer in a direction from the second layer toward the second region.

3. The substrate support according to claim 1, wherein the first layer includes a flow path through which a refrigerant is circulated.

4. The substrate support according to claim 3, wherein the transition region includes at least a part of the flow path.

5. The substrate support according to claim 3, wherein the transition region includes an entirety of the flow path.

6. The substrate support according to claim 1, wherein the second region contains at least one selected from the group consisting of aluminum nitride, a metal matrix composite, a composite of silicon and aluminum, a composite of silicon carbide and aluminum, a composite of silicon and titanium, a first metal, and an alloy including the first metal.

7. The substrate support according to claim 6, wherein the first metal includes at least one selected from the group consisting of titanium, molybdenum, tungsten, and tantalum.

8. The substrate support according to claim 1,
wherein the second layer has a third thermal conductivity, and
the first thermal conductivity is equal to or higher than the third thermal conductivity.

9. The substrate support according to claim 1, wherein the second thermal conductivity is 100 W/(m·K) or higher.

10. The substrate support according to claim 1,
wherein the transition region has a stack structure including a plurality of layers, and
the thermal conductivity of the transition region progressively shifts from the first region toward the second region.

11. The substrate support according to claim 1,
wherein the transition region is a single layer, and
the thermal conductivity of the transition region continuously shifts from the first region toward the second region.

12. The substrate support according to claim 1, wherein the second layer is formed of a ceramic material having a volume resistivity of 1×10¹⁵ Ω or more at a temperature equal to or higher than a room temperature and equal to or lower than 350° C.

13. The substrate support according to claim 1, wherein a thermal conductivity of the second layer is 50 W/(m·K) or less.

14. A substrate support comprising:
a first layer;
a second layer disposed on the first layer, including a substrate supporting surface to support a substrate and at least one adsorption electrode that controllably attracts the substrate, and made of a dielectric material having a volume resistance value higher than a volume resistance value of the first layer; and
a diffusion prevention layer provided between the first layer and the second layer and formed of a material which is the same as a material of the second layer,
wherein the first layer includes:
a first region in contact with the diffusion prevention layer and having a first thermal conductivity;
a second region having a second thermal conductivity higher than the first thermal conductivity and having a configuration in which the first region is disposed between the second region and the second layer; and
a transition region disposed between the first region and the second region and having a thermal conductivity that shifts within a range between the first thermal conductivity and the second thermal conductivity, and progressively approaches the second thermal conductivity according to an increase in distance from the first region in a direction from the first region toward the second region.

15. The substrate support according to claim 1,
wherein the second region has a bottom surface opposite to the substrate supporting surface,
the substrate support further includes a tube defining holes penetrating the first layer and the second layer from the bottom surface toward the substrate supporting surface, and
the tube is formed of an insulating material which is the same as the material of the second layer.

16. The substrate support according to claim 1,
wherein the second region has a bottom surface opposite to the substrate supporting surface,
the substrate support further includes a tube defining power supply holes each extending from the bottom surface to the adsorption electrode, and
the tube is formed of an insulating material which is the same as the material of the second layer.

17. The substrate support according to claim 1, further comprising an annular region surrounding a central region radially outside the central region including the first layer and the second layer,
wherein the annular region includes a third layer, and
a fourth layer disposed on the third layer and made of a dielectric material having a volume resistance value higher than a volume resistance value of the third layer, and the third layer includes
a third region provided on a side of the fourth layer and having the first thermal conductivity,
a fourth region having the second thermal conductivity higher than the first thermal conductivity and having a configuration in which the third region is disposed between the fourth region and the fourth layer, and
a transition region disposed between the third region and the fourth region and having a thermal conductivity that shifts within a range between the first thermal conductivity and the second thermal conductivity to approach the second thermal conductivity according to an increase in distance from the third region in a direction from the third region toward the fourth region.

18. The substrate support according to claim 17, wherein a groove is formed between the central region and the annular region.

19. The substrate support according to claim 14, further comprising:
a base including a flow path for circulating a refrigerant and configured to support the first layer; and
a bonding layer interposed between the first layer and the base and configured to connect the first layer to the base,
wherein the bonding layer contains an organic adhesive component and a filler having a thermal conductivity higher than a thermal conductivity of the organic adhesive component.

20. A substrate support including:
a first layer; and
a second layer disposed on the first layer and including a substrate supporting surface to support a substrate and at least one adsorption electrode that controllable attracts the substrate, wherein
the first layer includes a first region, a transition region, and a second region, the first region is in contact with the second layer and is disposed between the second region and the second layer, the transition region is disposed between the first region and the second region, the second region is formed of a first material including at least one selected from the group consisting of aluminum nitride, a metal matrix composite, a composite of silicon and aluminum, a composite of silicon carbide and aluminum, a composite of silicon and titanium, a first metal, and an alloy including the first metal,
the second layer is formed of a second material including alumina having 99.5 mass % or more, and
the first region and the transition region respectively include the first material and the second material and have a gradient composition in which a ratio of the first material to the second material increases according to an increase in distance from the second layer in a direction from the second layer toward the second region.

21. The substrate support according to claim 20, wherein the first metal includes at least one selected from the group consisting of titanium, molybdenum, tungsten, and tantalum.

22. A plasma processing apparatus comprising:
a chamber; and
the substrate support according to claim 1, which is disposed in the chamber.

23. A plasma processing apparatus comprising:
a chamber; and
the substrate support according to claim 14, which is disposed in the chamber.

24. A plasma processing apparatus comprising:
a chamber; and
the substrate support according to claim 20, which is disposed in the chamber.
